(19) United States
(12) Patent Application Publication
(10) Pub. No.: US 2025/0316476 A1
(43) Pub. Date: Oct. 9, 2025

(54) DENSIFICATION OF CARBON GAPFILL USING LOW FREQUENCY RADIO FREQUENCY (LFRF) TREATMENT

(71) Applicant: Applied Materials, Inc., Santa Clara, CA (US)

(72) Inventors: Vamshi Krishna GADDAMEDI, Sunnyvale, CA (US); Tze-Yu LIN, Santa Clara, CA (US); Anantha Venkataraman NAGARAJAN, Sunnyvale, CA (US); Peiqi WANG, Campbell, CA (US); Abdul Aziz KHAJA, San Jose, CA (US); Ewing CHEN, Los Angeles, CA (US)

(21) Appl. No.: 19/094,097

(22) Filed: Mar. 28, 2025

Related U.S. Application Data
(60) Provisional application No. 63/575,563, filed on Apr. 5, 2024.

(51) Int. Cl. H01L 21/02; H01J 37/32; H01L 21/3105

(52) U.S. Cl. CPC H01L 21/0234; H01J 37/32174; H01L 21/02115; H01L 21/31053; H01J 2237/336

(57) ABSTRACT

The present disclosure provides methods and apparatus that facilitate the formation of high-quality carbon gapfill structures and that address the issues related to conventional carbon gapfill methods. In certain embodiments, the carbon gapfill methods and apparatus described herein utilize a low frequency radio frequency (LFRF) biased plasma treatment to gapfill structures with high-quality and high-density carbon films.

### CROSS-REFERENCE TO RELATED APPLICATIONS

This application claims benefit of U.S. provisional patent application Ser. No. 63/575,563, filed Apr. 5, 2024, which is herein incorporated by reference in its entirety.

### INTRODUCTION

### Field

Integrated circuits are made possible by processes which produce intricately patterned material layers on substrate surfaces. Producing patterned materials on a substrate requires controlled methods of formation and removal of exposed materials.

As device sizes continue to shrink, material formation may affect subsequent operations of semiconductor device fabrication. For example, in certain gapfilling operations, a carbon material may be formed or deposited to fill a trench or other gap formed on a semiconductor substrate. However, as device features are characterized by higher aspect ratios and reduced critical dimensions, these gapfilling operations become increasingly challenging, and may result in decreased film quality and decreased overall gapfill performance. This can impact overall device performance and subsequent processing operations.

Thus, there is a need for improved gapfill systems and methods that can be used to produce high quality devices and structures. These and other needs are addressed by the present technology.

### SUMMARY

The present disclosure provides methods and apparatus that facilitate the formation of high-quality carbon gapfill structures and that address the issues related to conventional carbon gapfill methods.

In certain aspects, a processing method is provided, the processing method including: depositing a film onto a structure of a semiconductor substrate disposed in a processing region of a semiconductor processing chamber, the film including a carbon material; and exposing the semiconductor substrate to a low frequency radio frequency (LFRF) biased plasma treatment to densify the carbon material of the film deposited on the structure.

In certain aspects, a processing method is provided, the processing method including: depositing a carbon gapfill material into a gap of a semiconductor structure disposed in a processing region of a semiconductor processing chamber; exposing the semiconductor structure to a low frequency radio frequency (LFRF) biased plasma treatment to densify the carbon gapfill material; and planarizing the carbon gapfill material deposited onto the semiconductor structure.

In certain aspects, a processing method is provided, the processing method including: depositing a carbon gapfill material into a gap of a semiconductor structure disposed in a processing region of a semiconductor processing chamber; exposing the semiconductor structure to a dual-frequency biased plasma treatment to densify the carbon gapfill material, the dual-frequency biased plasma treatment including: applying a first radio frequency (RF) bias including a pulsed or continuous low frequency RF (LFRF) bias power; and applying a second RF bias including a continuous high frequency RF (HFRF) bias power; and planarizing the carbon gapfill material deposited onto the semiconductor structure.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a schematic cross-sectional view of an exemplary processing chamber, according to certain embodiments of the present disclosure.

FIG. 2 illustrates exemplary operations in a processing method, according to certain embodiments of the present disclosure.

FIGS. 3A-3C illustrate schematic cross-sectional views of a substrate during a processing, according to certain embodiments of the present disclosure.

Several of the Figures include schematic illustrations. It is to be understood that the Figures are for illustrative purposes, and are not to be considered of scale unless specifically stated to be of scale. Additionally, as schematic illustrations, the Figures are provided to aid in comprehension of the description and may not include all aspects or information compared to realistic representations, and may include exaggerated material for illustrative purposes.

In the appended Figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Carbon gapfill processes are essential in a wide range of patterning applications for forming semiconductor device features, and particularly, for advanced nodes such as A14 nodes and beyond. However, as overall dimensions of semiconductor devices continue to shrink, material layers need to be reduced in thickness and size to scale the features of such devices. And, as the device features are reduced in size, the aspect ratios of the features increase.

Conventional gapfill processes, and particularly, carbon gapfill processes, may be ineffective in uniformly filling gaps between these high aspect ratio features with dense, high-quality carbon material layers. For example, current spin-on carbon gapfill processes suffer from issues related to film density, etch selectivity, film shrinkage, film delamination, and the formation of undesired voids or seams in gapfill materials. Thus, such methods, as well as other conventional gapfill processes, have been limited in the ability to prevent structural flaws in the final fabricated devices. Still further, traditional spin-on carbon gapfilling methods often utilize multiple deposition-etch cycles, which can negatively impact overall fabrication costs, in addition to affecting film quality.

Yet, typical semiconductor device patterning techniques require high density films with high etch selectivity for enhanced pattern fidelity (i.e., good local critical dimension uniformity (LCDU) and global critical dimension uniformity (GCDU)). Therefore, conventional gapfill processes do not provide films with optimal performance characteristics for patterning of advanced node devices with high aspect ratio features.

The present disclosure provides methods and apparatus that facilitate the formation of high-quality and high-density carbon gapfill structures, and that address the issues related to conventional carbon gapfill methods. More particularly, the present disclosure provides novel methods and apparatus for carbon gapfill approaches that utilize low frequency radio frequency (LFRF) treatments. Such methods and apparatus enable the efficient formation of high-density carbon gapfill structures without sacrificing film quality or gapfill performance. For example, the current methods and apparatus reduce and/or eliminate the formation of voids and seams in deposited carbon gapfill films, leading to the mitigation and/or elimination of film shrinkage and subsequent film delamination.

In certain embodiments, the present disclosure provides an LFRF plasma treatment, and related chemistries, that is applied during and/or after the deposition of carbon gapfill films via plasma enhanced CVD (PECVD). The LFRF plasma treatment facilitates the formation of high-density carbon gapfill films for filling even the most complex of structures without the formation of seams or voids. In certain embodiments, the LFRF plasma treatment is applied during and/or after a PECVD gapfill process performed at high temperatures and utilizing C2H2 and/or C2H6 and/or C6H6 and/or H2 precursors, as well as He, Ar, and/or N2. A more particular description of a gapfill process utilizing an LFRF plasma treatment may be had by reference to embodiments, some of which are illustrated in the Figures and described below.

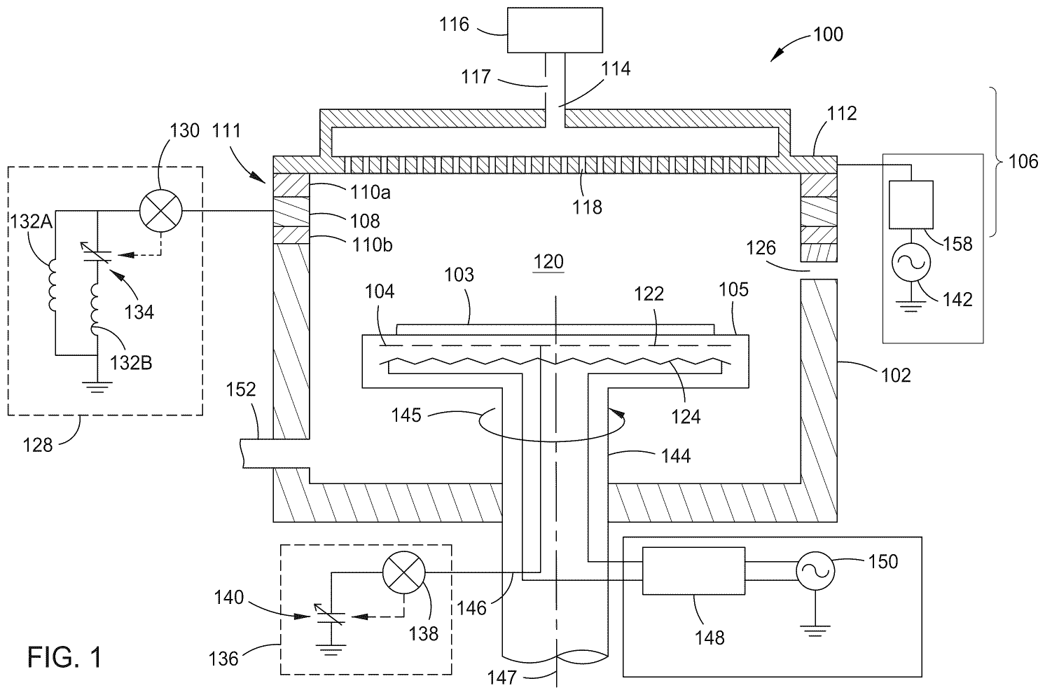

FIG. 1 illustrates a cross-sectional view of an exemplary processing chamber 100, according to certain embodiments of the present disclosure. FIG. 1 provides an overview of a system incorporating one or more aspects of the present disclosure, and/or which may perform one or more deposition or other processing operations according to embodiments of the present disclosure. Additional details of chamber 100 or methods performed may be described further below. The processing chamber 100 may be utilized to form film layers, e.g., for gapfilling, according to certain embodiments of the present disclosure, although it is to be understood that the methods may similarly be performed in any chamber within which film formation may occur. In certain embodiments, the processing chamber 100 is a PECVD chamber.

The processing chamber 100 may include a chamber body 102, a substrate support 104 disposed inside the chamber body 102, and a lid assembly 106 coupled with the chamber body 102 and enclosing the substrate support 104 in a processing volume 120. A substrate 103 may be provided to the processing volume 120 through an opening 126, which may be conventionally sealed for processing using a slit valve or door. The substrate 103 may be seated on a surface 105 of the substrate support during processing. The substrate support 104 may be rotatable, as indicated by the arrow 145, along an axis 147, where a shaft 144 of the substrate support 104 may be located. Alternatively, the substrate support 104 may be lifted up to rotate, as necessary, during a deposition process. Additionally, the substrate support 104 include a cooling device and may be configured to be chilled, e.g., less than or about 100° C., or less than or about 90° C., or less than or about 80° C., or less than or about 70° C., or less than or about 60° C., or less than or about 50° C., or less than or about 40° C., or less than or about 30° C., or less than or about 20° C., or less than or about 10° C., or less.

A plasma profile modulator 111 may be disposed in the processing chamber 100 to control plasma distribution across the substrate 103 disposed on the substrate support 104. The plasma profile modulator 111 may include a first electrode 108 that may be disposed adjacent to the chamber body 102, and may separate the chamber body 102 from other components of the lid assembly 106. The first electrode 108 may be part of the lid assembly 106, or may be a separate sidewall electrode. The first electrode 108 may be an annular or ring-like member, and may be a ring electrode. The first electrode 108 may be a continuous loop around a circumference of the processing chamber 100 surrounding the processing volume 120, or may be discontinuous at selected locations if desired. The first electrode 108 may also be a perforated electrode, such as a perforated ring or a mesh electrode, or may be a plate electrode, such as, for example, a secondary gas distributor.

One or more isolators 110a, 110b, which may be a dielectric material such as a ceramic or metal oxide, for example aluminum oxide and/or aluminum nitride, may contact the first electrode 108 and separate the first electrode 108 electrically and thermally from a gas distributor 112 and from the chamber body 102.

The gas distributor 112 may define apertures 118 for distributing process precursors into the processing volume 120. The gas distributor 112 may be a conductive gas distributor or a non-conductive gas distributor. Accordingly, the gas distributor 112 may be formed of conductive and non-conductive components. For example, a body of the gas distributor 112 may be conductive while a face plate of the gas distributor 112 may be non-conductive. The gas distributor 112 may be powered, such as by a first source of electric power 142 as shown in FIG. 1, or the gas distributor 112 may be coupled with ground in certain embodiments.

The gas distributor 112 may be coupled with a first source of electric power 142, such as a continuous or pulsed radio frequency (RF) power source (i.e., an RF generator), a continuous or pulsed direct current (DC) power source (i.e., a DC generator), any other power source that can be coupled with the processing chamber 100, or a combination of these or other power sources. In certain embodiments, the first source of electric power 142 generates and provides RF bias power to the gas distributor 112. In such embodiments, the first source of electric power 142 is configured to generate a continuous or pulsed RF bias at low frequencies (low frequency RF (LFRF)), such as between about 350 kHz and about 2 MHz, and/or high frequencies (high frequency RF (HFRF), such as between about 13.56 MHz and about 2 MHz. The gas distributor 112 may be coupled with the first source of electric power 142 through a filter 158, which may be an impedance matching circuit.

The first electrode 108 may be coupled with a first tuning circuit 128 that may control a ground pathway of the processing chamber 100. The first tuning circuit 128 may include a first electronic sensor 130 and a first electronic controller 134. The first electronic controller 134 may be or include a variable capacitor or other circuit elements. The first tuning circuit 128 may be or include one or more inductors 132. The first tuning circuit 128 may be any circuit that enables variable or controllable impedance under the plasma conditions present in the processing volume 120 during processing. In certain embodiments as illustrated, the first tuning circuit 128 may include a first circuit leg and a second circuit leg coupled in parallel between ground and the first electronic sensor 130. The first circuit leg may include a first inductor 132A. The second circuit leg may include a second inductor 132B coupled in series with the first electronic controller 134. The second inductor 132B may be disposed between the first electronic controller 134 and a node connecting both the first and second circuit legs to the first electronic sensor 130. The first electronic sensor 130 may be a voltage or current sensor and may be coupled with the first electronic controller 134, which may afford a degree of closed-loop control of plasma conditions inside the processing volume 120.

A second electrode 122 may be coupled with the substrate support 104. The second electrode 122 may be embedded within the substrate support 104 or coupled with a surface of the substrate support 104. The second electrode 122 may be a plate, a perforated plate, a mesh, a wire screen, or any other distributed arrangement of conductive elements. The second electrode 122 may be a tuning electrode, and may be coupled with a second tuning circuit 136 by a conduit 146, for example a cable having a selected resistance, such as 50 ohms, for example, disposed in the shaft 144 of the substrate support 104. The second tuning circuit 136 may have a second electronic sensor 138 and a second electronic controller 140, which may be a second variable capacitor. The second electronic sensor 138 may be a voltage or current sensor, and may be coupled with the second electronic controller 140 to provide further control over plasma conditions in the processing volume 120.

In certain embodiments, a third electrode 124, which may be an electrostatic chucking electrode and/or a bias electrode, may be coupled with the substrate support 104. The third electrode may be coupled with a second source of electric power 150 through a filter 148, which may be an impedance matching circuit. The second source of electric power 150 may be a continuous or pulsed DC power source, a continuous or pulsed RF power source, or a combination of these or other power sources. In certain embodiments, the second source of electric power 150 may be configured to generate an RF bias power (e.g., configured to provide a continuous or pulsed RF bias at low frequencies, such as between about 350 kHz and about 2 MHz, and/or high frequencies, such as between about 13.56 MHz and about 2 MHz).

The lid assembly 106 and substrate support 104 of FIG. 1 may be used with any processing chamber for plasma or thermal processing. In operation, the processing chamber 100 may afford real-time control of plasma conditions in the processing volume 120. The substrate 103 may be disposed on the substrate support 104, and process gases may be flowed through the lid assembly 106 using an inlet 114 according to any desired flow plan. Inlet 114 may include delivery from a remote plasma source unit 116, which may be fluidly coupled with the chamber, as well as a bypass 117 for process gas delivery that may not flow through the remote plasma source unit 116 in certain embodiments. Gases may exit the processing chamber 100 through an outlet 152. Electric power may be coupled with the gas distributor 112 to establish a plasma in the processing volume 120.

Upon energizing a plasma in the processing volume 120, a potential difference may be established between the plasma and the gas distributor 112, the first electrode, and/or the second electrode 122. The electronic controllers 134, 140 may then be used to adjust the flow properties of the ground paths represented by the two tuning circuits 128 and 136. A set point may be delivered to the first tuning circuit 128 and the second tuning circuit 136 to provide independent control of deposition rate and of plasma density uniformity from center to edge. In embodiments where the electronic controllers may both be variable capacitors, the electronic sensors may adjust the variable capacitors to maximize deposition rate and minimize thickness non-uniformity independently.

Each of the tuning circuits 128, 136 may have a variable impedance that may be adjusted using the respective electronic controllers 134, 140. Where the electronic controllers 134, 140 are variable capacitors, the capacitance range of each of the variable capacitors, and the inductances of the first inductor 132A and the second inductor 132B, may be chosen to provide an impedance range. This range may depend on the frequency and voltage characteristics of the plasma, which may have a minimum in the capacitance range of each variable capacitor. Hence, when the capacitance of the first electronic controller 134 is at a minimum or maximum, impedance of the first tuning circuit 128 may be high, resulting in a plasma shape that has a minimum aerial or lateral coverage over the substrate support. When the capacitance of the first electronic controller 134 approaches a value that minimizes the impedance of the first tuning circuit 128, the aerial coverage of the plasma may grow to a maximum, effectively covering the entire working area of the substrate support 104. As the capacitance of the first electronic controller 134 deviates from the minimum impedance setting, the plasma shape may shrink from the chamber walls and aerial coverage of the substrate support may decline. The second electronic controller 140 may have a similar effect, increasing and decreasing aerial coverage of the plasma over the substrate support as the capacitance of the second electronic controller 140 may be changed.

The electronic sensors 130, 138 may be used to tune the respective circuits 128, 136 in a closed loop. A set point for current or voltage, depending on the type of sensor used, may be installed in each sensor, and the sensor may be provided with control software that determines an adjustment to each respective electronic controller 134, 140 to minimize deviation from the set point. Consequently, a plasma shape may be selected and dynamically controlled during processing. It is to be understood that, while the foregoing discussion is based on electronic controllers 134, 140, which may be variable capacitors, any electronic component with adjustable characteristic may be used to provide tuning circuits 128 and 136 with adjustable impedance.

Processing chamber 100 may be utilized in certain embodiments of the present disclosure for processing methods that may include formation, treatment, etching, or conversion of materials for semiconductor structures. It is to be understood that the chamber described is not to be considered limiting, and any chamber that may be configured to perform operations as described may be similarly used.

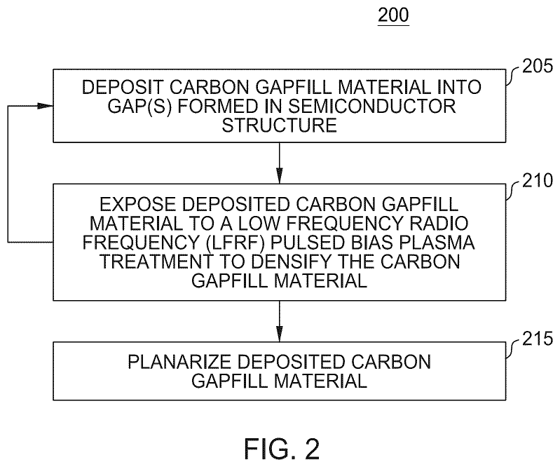

FIG. 2 illustrates a flow diagram of exemplary operations in a processing method 200, according to certain embodiments of the present disclosure. The method 200 generally includes a PECVD carbon gapfill deposition process. The method 200 may be performed in a variety of processing chambers and on one or more mainframes or tools, including processing chamber 100 described above. Method 200 may include a number of optional operations, which may or may not be specifically associated with certain embodiments of methods according to the present technology. For example, certain operations may be described in order to provide a broader scope of the structural formation, but are not critical to the technology, or may be performed by alternative methodology as would be readily appreciated.

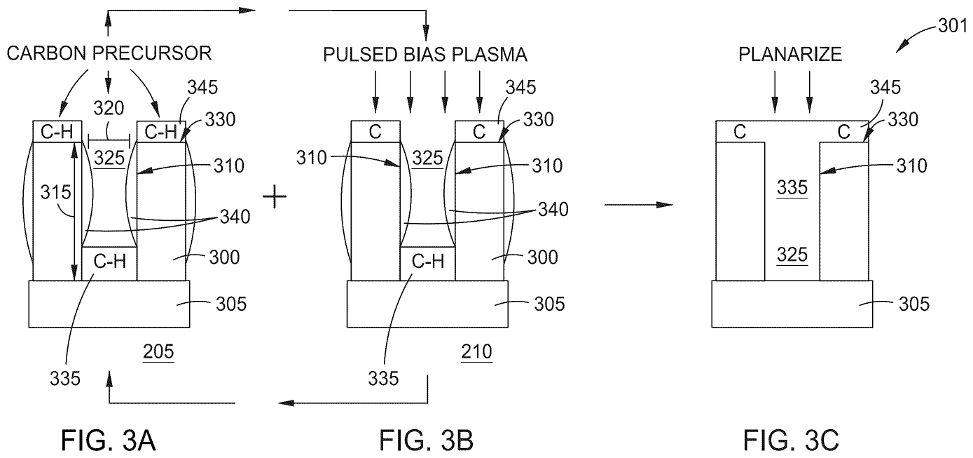

The operations of method 200 are schematically illustrated in FIGS. 3A-3C, the illustrations of which will be described in conjunction with the operations of method 200. It is to be understood that the Figures illustrate only partial schematic views, and that a substrate may contain any number of additional layers, materials, and/or features having a variety of characteristics and aspects as illustrated in the Figures.

In certain embodiments, method 200 may include additional operations prior to initiation of the listed operations in FIG. 2. For example, additional processing operations may include forming structures on a semiconductor substrate, which may include both forming and removing material. For example, transistor structures, memory structures, or any other structures may be formed. Prior processing operations may be performed in the chamber in which method 200 may be performed, e.g., chamber 100, or processing may be performed in one or more other processing chambers prior to delivering the substrate into the semiconductor processing chamber or chambers in which method 200 may be performed. Regardless, method 200 may optionally include delivering a semiconductor substrate to a processing region of a semiconductor processing chamber, such as processing chamber 100 described above, or other chambers that may include components as described above. The substrate may be placed on a substrate support, which may be a pedestal such as substrate support 104, and which may reside in a processing region of the chamber, such as processing volume 120 described above.

Turning to FIGS. 3A-3C, a partial view of a substrate 305 having a structure 300 formed thereon is shown. Substrate 305 may represent a substrate on which several operations have been performed, and on which semiconductor processing may be performed. It is to be understood that structure 300 may be representative of only a few top layers formed on the substrate 305 during processing to illustrate aspects of the present technology, and that one or more intermediate layers may be disposed between the structure 300 and the substrate 305. Thus, when referencing the substrate 305, the present disclosure may refer to the substrate 305 and/or one or more intermediate layers disposed on the substrate 305 and below the structure 300.

The substrate 305 and/or the structure 300 may include one or more materials used in semiconductor processing. For example, the material(s) may be or include silicon, germanium, dielectric materials including silicon oxide or silicon nitride, other oxide or nitride materials, metal materials, or any number of combinations of these materials. The structure 300 may be characterized by any shape or configuration according to the present technology. In certain embodiments, the structure 300 includes a trench or aperture 325 formed on the substrate 305.

Although the structure 300 may be characterized by any shape or size, in certain embodiments, the structure 300 is characterized by a high aspect ratio, or a ratio of a depth 315 of the structure to a width or diameter 320 across the structure. For example, in certain embodiments, structure 300 may be characterized by an aspect ratio greater than or about 5:1, or may be characterized by an aspect ratio greater than or about 10:1, greater than or about 15:1, greater than or about 20:1, greater than or about 25:1, greater than or about 30:1, greater than or about 40:1, greater than or about 50:1, or greater. Additionally, the structure 300 may be characterized by a narrow width or diameter 320 across the structure including between two sidewalls 310, such as a dimension less than or about 20 nm, and may be characterized by a width or diameter 320 across the structure of less than or about 15 nm, or less than or about 12 nm, or less than or about 10 nm, or less than or about 9 nm, or less than or about 8 nm, or less than or about 7 nm, or less than or about 6 nm, or less than or about 5 nm, or less. However, in certain embodiments, structure 300 may be characterized by an aspect ratio less than or about 5:1, or may be characterized by an aspect ratio less than or about 5:2, or less than or about 5:3, or less than or about 5:4, or less than or about 1:1, or less. In certain embodiments, the structure 300 may be characterized by a width or diameter greater than or about 20 nm.

Returning to FIG. 2, in certain embodiments, method 200 may include optional treatment operations, such as a pretreatment or pre-clean process, that may be performed to prepare one or more surface(s) of the substrate 305 and/or structure 300 for deposition of a carbon gapfill.

Once the surfaces are prepared, at operation 205 and as shown in FIG. 3A, the method 200 includes depositing a carbon gapfill material into one or more gaps formed in the structure 300, such as trench or aperture 325. In certain embodiments, operation 205 includes delivering one or more precursors to a processing region of a semiconductor processing chamber housing the structure 300. The precursors may include one or more carbon-containing precursors, such as hydrocarbons, as well as one or more diluents or carrier gases such as an inert gas or other gas delivered with the carbon-containing precursor. A plasma may be formed from the deposition precursors, including the carbon-containing precursor. The plasma may be formed within the processing region, which may allow deposition materials to deposit on the substrate. For example, in certain embodiments a capacitively-coupled plasma may be formed within the processing region by applying plasma power to the faceplate as previously described. In certain embodiments, however, the plasma may be formed external to the processing region, such as by a remote plasma source (e.g., remote plasma source unit 116 described above), and delivered to the processing region.

In certain embodiments, the carbon-containing precursor(s) delivered to the processing region include an aliphatic hydrocarbon, such as an alkane, alkene, alkyne, cycloalkane, or alkadiene. Examples of aliphatic hydrocarbon include 1,5-hexadiene, ethylene, propylene, acetylene, methane, and the like. In certain embodiments, the carbon-containing precursor(s) delivered to the processing region include a vinyl group-based hydrocarbon precursor. Examples of vinyl group-based precursors include 5-vinyl-2-norbornene and other norbornene compounds.

High density carbon gapfill can be formed by optimizing H:C carbon ratios during the gapfill deposition process. For example, when using acetylene (C2H2) as a precursor, additional hydrogen (H2) may need to be flowed into the process volume. However, propylene (C3H6) inherently has a high hydrogen composition, which minimizes the hydrogen flow rate requirements during deposition. And, without flowing additional hydrogen during the deposition process, the film quality of the deposited gapfill can be enhanced. Likewise, using benzene (C6H6) or similar chemistries can also lead to carbon gapfill films with improved density and quality.

As noted above, a carbon-containing material may be deposited on the structure 300 and/or substrate 305 at operation 205 from plasma effluents of the carbon-containing precursor. The materials may at least partially deposit within gaps formed the structure 300, such as within trench or aperture 325, to provide a bottom-up type of gapfill. As illustrated in FIG. 3A, although most of the gapfill material 335 may be deposited at the bottom of the structure 300 and on the substrate 305, a small amount of material may also be deposited on the sidewalls 310 of the structure 300, as illustrated with gapfill material 340, as well as on top of, or between, structure 300, as illustrated by gapfill material 345 on top surface 330 of structure 300.

The source power applied to generate and sustain a plasma during the deposition process at operation 205 may be a lower source power, which may limit dissociation, and which may maintain an amount of hydrogen incorporation in the deposited materials. Additionally, unlike conventional technologies, the present technology may incorporate RF biasing, including a low frequency radio frequency (LFRF) bias, and in certain embodiments, a high frequency RF (HFRF) bias, which may facilitate treatment of the deposited film during (and/or after, as described with reference to operation 210) the deposition process. Thus, operation 205 may include utilizing a source power, such as coupled with the faceplate or showerhead as previously described, as well as utilizing a bias power, such as applied through the faceplate or showerhead (e.g., a top feed bias), or the substrate support (e.g., a bottom feed bias), as discussed above.

In certain embodiments, a source power (e.g., as generated and applied to the faceplate or showerhead by the first source of electric power 142), may be pulsed, and the duty cycle may be reduced, which may further reduce the effective plasma power. For example, the source power may be applied at any higher frequency, such as greater than or about 10 MHz, greater than or about 13 MHz, greater than or about 15 MHz, greater than or about 20 MHz, or higher. The source power may be less than or about 300 W, or less than or about 250 W, or less than or about 200 W, or less than or about 150 W, or less than or about 100 W, or less than or about 50 W, or less. Additionally, the source power may be pulsed at a pulsing frequency of 20 kHz or less, such as less than or about 15 kHz, or less than or about 12 kHz, or less than or about 10 kHz, or less than or about 8 kHz, or less. Additionally, the pulsing duty cycle may be applied at less than or about 50%, and may be applied at less than or about 40%, or less than or about 30%, or less than or about 20%, or less than or about 10%, or less than or about 5%, or less than or about 1% or less.

In certain embodiments, a bias power may be generated and applied to the faceplate or showerhead by the first source of electric power 142 or to the substrate support by the second source of electric power 150. The bias power may be provided at a low frequency radio frequency (LFRF), such as less than or about 2 MHz, or less than or about 1.5 MHz, or less than or about 1 MHz, or less than or about 750 kHz, or less than or about 500 kHz, or less than or about 450 kHz, or less than or about 400 kHz, or less than or about 350 kHz, or less. The LFRF bias power may have a power of less than or about 900 W, or less than or about 600 W, or less than or about 300 W, or less than or about 200 W, or less than or about 100 W, or less than or about 50 W, or less. In certain embodiments, the LFRF bias power is applied at a power of about 100 W to about 900 W. Additionally, the LFRF bias power may be pulsed at a pulsing frequency of 2 kHz or less, such as less than or about 1.5 kHz, or less than or about 1 kHz, or less than or about 900 Hz, or less than or about 800 Hz, or less than or about 700 Hz, or less than or about 600 Hz, or less than or about 500 Hz, or less than or about 400 Hz, or less than or about 300 Hz, or less than or about 200 Hz, or less than or about 100 Hz, or less. In certain embodiments, the pulse frequency is between about 200 Hz and about 2 kHz. Additionally, the pulsing duty cycle of the LFRF bias power may be applied at less than or about 80%, or less than or about 70%, or less than or about 60%, or less than or about 50%, or less than or about 40%, or less than or about 30%, or less than or about 20%, or less than or about 10%, or less than or about 6%, or less than or about 5%, or less than or about 1%, or less. In certain embodiments, the duty cycle is between about 10% and about 70%.

In certain embodiments, dual-frequency biasing may be performed at operation 205. In such embodiments, a second bias power may be generated and applied to the faceplate or showerhead by the first source of electric power 142 or to the substrate support by the second source of electric power 150. The second bias power may be provided at a higher RF frequency than the LFRF bias power (e.g., at a high frequency radio frequency (HFRF)), such as greater than or about 10 MHz, greater than or about 13 MHz, greater than or about 15 MHz, greater than or about 20 MHz, greater than or about 27 MHz, or higher. The HFRF bias may have a power of more than or about 800 W, or more than or about 1000 W, or more than or about 1200 W, or more than or about 1400 W, or more than or about 1600 W, or more than or about 1800 W, or more than or about 2000 W, or more than or about 2200 W, or more than or about 2400 W, or more than or about 2600 W, or more than or about 2800 W, or more than or about 2900 W, or more. In certain embodiments, the HFRF bias power is applied at a power of about 800 W to about 2000 W Additionally, the HFRF bias power may be pulsed at a pulsing frequency of 20 kHz or less, such as less than or about 15 kHz, or less than or about 12 kHz, or less than or about 10 kHz, or less than or about 8 kHz, or less than or about 6 kHz, or less than or about 4 kHz, or less than or about 2 kHz, or less. Additionally, the pulsing duty cycle of the HFRF bias may be applied at less than or about 50%, and may be applied at less than or about 40%, or less than or about 30%, or less than or about 20%, or less than or about 10%, or less than or about 5%, or less than or about 1% or less.

In certain embodiments, a LFRF bias power and/or a HFRF bias power may be continuously generated and provided to the processing chamber 100.

In certain embodiments, to facilitate dissociation and deposition, the deposition precursors may include one or more inert diluent gases, such as argon (Ar) and/or helium (He), and/or xenon (Xe), krypton (Kr), and/or the like, which may help improve dissociation. For example, argon may be delivered with the carbon-containing precursor at a flow rate ratio of the argon to the carbon-containing precursor of greater than or about 0.1:1, and may be delivered at a flow rate ratio of greater than or about 0.5:1, greater than or about 0.9:1, greater than or about 1:1, greater than or about 1.8:1, greater than or about 2:1, greater than or about 2.7:1, greater than or about 3.0:1, greater than or about 3.6:1, or more. In certain embodiments, ammonia may be delivered with the carbon-containing precursor and/or argon at a flow rate ratio of the ammonia to the carbon-containing precursor of greater than or about 0.2:1, and may be delivered at a flow rate ratio of greater than or about 0.4:1, greater than or about 0.6:1, greater than or about 0.8:1, greater than or about 1:1, greater than or about 1.2:1, greater than or about 1.4:1, greater than or about 1.6:1, or more.

In certain embodiments, a flow rate of the carbon-containing precursor is greater than or about 60 sccm, greater than or about 80 sccm, greater than or about 100 sccm, or greater than or about 200 sccm, or greater than or about 3000 300 sccm, or greater than or about 400 sccm, or greater than or about 500 sccm, or greater than or about 600 sccm, or greater than or about 700 sccm, or greater than or about 800 sccm, or greater than or about 900 sccm, or greater than or about 1000 sccm, or more.

In certain embodiments, a flow rate of helium, argon, xenon, krypton, and/or other diluent(s) is greater than or about 100 sccm, or greater than or about 500 sccm, or greater than or about 1000 sccm, or greater than or about 2000 sccm, or greater than or about 3000 sccm, or greater than or about 4000 sccm, or greater than or about 5000 sccm, or greater than or about 6000 sccm, or greater than or about 7000 sccm, or greater than or about 8000 sccm, or greater than or about 9000 sccm, or greater than or about 10000 sccm, or greater than or about 11000 sccm, or greater than or about 12000 sccm, or more. In certain embodiments, a flow rate of hydrogen, carbon dioxide, and/or ammonia is greater than or about 50 sccm, or greater than or about 75 sccm, or greater than or about 100 sccm, or greater than or about 250 sccm, or greater than or about 500 sccm, or greater than or about 750 sccm, or greater than or about 1000 sccm, or greater than or about 2000 sccm, or greater than or about 3000 sccm, or greater than or about 4000 sccm, or greater than or about 5000 sccm, or greater than or about 6000 sccm, or more.

In certain embodiments, carbon gapfill material may be deposited on the structure 300 and/or substrate 305 at operation 205 at a controlled deposition rate of about 50 A/min or more, or about 100 A/min or more, about 155 A/min or more, about 200 A/min or more, or more.

Temperature and pressure may also impact deposition of the carbon gapfill material at operation 205. In certain embodiments, operation 205 may be performed at a chamber temperature below or about 100° C., and may be performed at a temperature less than or about 80° C., or less than or about 60° C., or less than or about 40° C., or less than or about 30° C., or less than or about 20° C., or less than or about 10° C., or lower. In certain embodiments, pressure within the chamber may be kept relatively low, such as at a chamber pressure of less than or about 40 Torr, or less than or about 30 Torr, or less than or about 20 Torr, and pressure may be maintained at less than or about 15 Torr, or less than or about 10 Torr, or less than or about 5 Torr, or less than or about 3 Torr, or less than or about 2 Torr, or less than or about 1 Torr, or less than or about 0.1 Torr, or less.

In certain embodiments, the deposition of the carbon gapfill material at operation 205 is carried out for a period of about 5 seconds or more, or about 10 seconds or more, about 15 seconds or more, about 20 seconds or more, about 25 seconds or more, or more.

Once the carbon gapfill material is deposited on the structure 300 and/or substrate 305, at operation 210 of the method 200 and as shown in FIG. 3B, the deposited carbon gapfill material is exposed to an LFRF biased plasma treatment to densify the material. The LFRF biased plasma treatment at operation 210 converts carbon-hydrogen bonds of the carbon gapfill material to carbon-carbon bonds, thereby resulting in a higher density, and thus high quality, carbon film. Although the deposited carbon gapfill film may shrink by performing this LFRF biased plasma treatment, such shrinkage is mitigated by the high planarity of the deposited gapfill material as facilitated by described techniques. In certain embodiments, operation 210 is performed in the same chamber as operation 205. In certain embodiments, the substrate 305 and structure 300 formed thereon are transferred to a different chamber upon deposition of the carbon gapfill material to perform operation 210.

In certain embodiments, operation 210 includes delivering one or more gases to the processing region of the semiconductor processing chamber housing the structure 300 to form a treatment gas mixture. A plasma may be formed from the treatment gas mixture. The plasma may be formed within the processing region, such as by applying plasma power to the faceplate as previously described. In certain embodiments, however, the plasma may be formed external to the processing region, such as by a remote plasma source (e.g., remote plasma source unit 116 described above), and delivered to the processing region.

In certain embodiments, the treatment gas mixture may include one or more inert diluent gases, such as argon (Ar) and/or helium (He), and/or xenon (Xe), krypton (Kr), and/or the like, which may help improve dissociation. In certain embodiments, a flow rate of helium, argon, xenon, krypton, and/or other diluent(s) is greater than or about 100 sccm, or greater than or about 500 sccm, or greater than or about 1000 sccm, or greater than or about 2000 sccm, or greater than or about 3000 sccm, or greater than or about 4000 sccm, or greater than or about 5000 sccm, or greater than or about 6000 sccm, or greater than or about 7000 sccm, or greater than or about 8000 sccm, or greater than or about 9000 sccm, or greater than or about 10000 sccm, or greater than or about 11000 sccm, or greater than or about 12000 sccm, or more. In certain embodiments, a flow rate of hydrogen, carbon dioxide, and/or ammonia is greater than or about 50 sccm, or greater than or about 75 sccm, or greater than or about 100 sccm, or greater than or about 250 sccm, or greater than or about 500 sccm, or greater than or about 750 sccm, or greater than or about 1000 sccm, or greater than or about 2000 sccm, or greater than or about 3000 sccm, or greater than or about 4000 sccm, or greater than or about 5000 sccm, or greater than or about 6000 sccm, or more.

As noted above, operation 210 includes the application of an LFRF bias to the generated plasma. In certain embodiments, an LFRF bias power is generated and applied to the faceplate or showerhead by the first source of electric power 142, or to the substrate support by the second source of electric power 150. The LFRF bias power may be provided at a low RF frequency of less than or about 2 MHz, or less than or about 1.5 MHz, or less than or about 1 MHz, or less than or about 750 kHz, or less than or about 500 kHz, or less than or about 450 kHz, or less than or about 400 kHz, or less than or about 350 kHz, or less. The LFRF bias power may have a power of less than or about 900 W, or less than or about 600 W, or less than or about 300 W, or less than or about 200 W, or less than or about 100 W, or less than or about 50 W, or less. In certain embodiments, the LFRF bias power is applied at a power of about 100 W to about 900 W. Additionally, the LFRF bias power may be pulsed at a pulsing frequency of 2 kHz or less, such as less than or about 1.5 kHz, or less than or about 1 kHz, or less than or about 900 Hz, or less than or about 800 Hz, or less than or about 700 Hz, or less than or about 600 Hz, or less than or about 500 Hz, or less than or about 400 Hz, or less than or about 300 Hz, or less than or about 200 Hz, or less than or about 100 Hz, or less. In certain embodiments, the pulsing frequency is between about 200 Hz and about 2 kHz. Additionally, the pulsing duty cycle of the LFRF bias power may be applied at less than or about 80%, or less than or about 70%, or less than or about 60%, or less than or about 50%, or less than or about 40%, or less than or about 30%, or less than or about 20%, or less than or about 10%, or less than or about 6%, or less than or about 5%, or less than or about 1%, or less. In certain embodiments, the duty cycle is between about 10% and about 70%.

In certain embodiments, dual-frequency biasing may be utilized at operation 210. In such embodiments, a second bias power may also be generated and applied to the faceplate or showerhead by the first source of electric power 142 or to the substrate support by the second source of electric power 150. The second bias power may be provided at a higher RF frequency than the LFRF bias power (e.g., at a high frequency radio frequency (HFRF)), such as greater than or about 10 MHz, greater than or about 13 MHz, greater than or about 15 MHz, greater than or about 20 MHz, greater than or about 27 MHz, or higher. The HFRF bias may have a power of more than or about 800 W, or more than or about 1000 W, or more than or about 1200 W, or more than or about 1400 W, or more than or about 1600 W, or more than or about 1800 W, or more than or about 2000 W, or more than or about 2200 W, or more than or about 2400 W, or more than or about 2600 W, or more than or about 2800 W, or more than or about 2900 W, or more. In certain embodiments, the HFRF bias power is applied at a power of about 800 W to about 2000 W. Additionally, the HFRF bias power may be pulsed at a pulsing frequency of 20 kHz or less, such as less than or about 15 kHz, or less than or about 12 kHz, or less than or about 10 kHz, or less than or about 8 kHz, or less than or about 6 kHz, or less than or about 4 kHz, or less than or about 2 kHz, or less. Additionally, the pulsing duty cycle of the HFRF bias may be applied at less than or about 50%, and may be applied at less than or about 40%, or less than or about 30%, or less than or about 20%, or less than or about 10%, or less than or about 5%, or less than or about 1% or less.

In certain embodiments, where dual-frequency biasing is performed at operation 210, a first bias power includes a low frequency radio frequency (LFRF), such as about 350 kHz or 2 MHz, and a second bias power includes a high frequency radio frequency (HFRF), such as about 13 MHz or 27 MHz. In certain embodiments, the HFRF bias power is applied continuously, while the LFRF bias power is pulsed at the parameters described above. In certain embodiments, both the HFRF bias power and the LFRF bias power are applied continuously. In still further embodiments, only a continuous LFRF bias power is applied to the processing chamber 100, without application of an HFRF bias power (e.g., single frequency biasing).

In certain embodiments, LFRF biasing can be utilized during the treatment process at operation 210 to create an amount of directionality for movement of generated plasma species, and more specifically, to create a downward movement of plasma effluents toward the structure 300. Thus, the plasma effluents can be directed toward surfaces normal to the direction of travel, such as material along the bottom of the structure 300 (e.g., bottom of the trench or aperture 325), as compared to surfaces parallel to the direction of travel (e.g., sidewalls 310). As a result, carbon gapfill material at the bottom of the trench or aperture 325 can be densified while material deposited on sidewalls 310 is not.

In certain embodiments, operation 210 may be performed at a temperature below or about 100° C., and may be performed at a temperature less than or about 80° C., or less than or about 60° C., or less than or about 40° C., or less than or about 30° C., or less than or about 20° C., or lower. Pressure within the chamber may be kept relatively low, such as at a chamber pressure of less than or about 40 Torr, or less than or about 30 Torr, or less than or about 20 Torr, and pressure may be maintained at less than or about 15 Torr, or less than or about 10 Torr, or less than or about 5 Torr, or less than or about 3 Torr, or less than or about 2 Torr, or less than or about 1 Torr, or less than or about 0.1 Torr, or less.

In certain embodiments, the LFRF biased plasma treatment at operation 210 is carried out for a period of about 5 seconds or more, or about 10 seconds or more, about 15 seconds or more, about 20 seconds or more, about 25 seconds or more, about 30 seconds or more, or more.

After performance of operation 210, operations 205 and 210 of the method 200 may be repeated as needed until the trench or aperture 325 of structure 300 has a desired amount of carbon gapfill material formed therein, thereby resulting in a gapfilled structure 301 as shown in FIG. 3C. For example, operations 205 and 210 can be iteratively performed for one or more cycles, such as for 5 or more cycles, such as for 10 or more cycles, such as for 15 or more cycles, such as for 20 or more cycles, such as for 25 or more cycles, or more, prior to performance of operation 215.

Subsequent to the LFRF biased plasma treatment to densify the deposited carbon gapfill material, a planarization process may be optionally performed at operation 215, as further shown in FIG. 3C. The planarization process at operation 215 may be performed to planarize the gapfill material 345 deposited on the top surface 330 of structure 300, and/or gapfill material 335 and/or gapfill material 340 extending out from trench or aperture 325.

In certain embodiments, the planarization process may include a chemical mechanical polishing (CMP) process. In general, the CMP process may include contacting the gapfill material(s) of gapfilled structure 301 to be planarized with a polishing pad and moving the polishing pad, the gapfilled structure 301, or both, hence creating relative movement between the gapfilled material(s) and the polishing pad, in the presence of a polishing fluid. Portions of the gapfilled material(s) may then be removed across the top of the gapfilled structure 301 in contact with the polishing pad through a combination of chemical and mechanical activity, which is provided at least in part by the polishing fluid. Commonly used polishing fluids include abrasive particle-containing slurries, e.g., colloids or suspensions, reactive liquid (abrasive-free) slurries, and abrasive-free or reduced-abrasive polishing fluids used in conjunction with fixed-abrasive polishing pads having abrasive particles disposed therein. As a result, the CMP process can form a planar top surface on the gapfilled structure 301 by planarizing the gapfilled material(s).

The gapfilling process described with reference to method 200 facilitates the formation of a high-quality and stable carbon film that mitigates or overcomes many of the issues of conventional carbon gapfilling processes. In certain embodiments, after performance of operation 210, the gapfilled structure 301 may be exposed to additional operations to fabricate a completed semiconductor device, including formation of additional structures on substrate 305. In certain embodiments, such additional operations include the performance of an etch on the gapfilled structure 301.

While the foregoing is directed to embodiments of the present disclosure, other and further embodiments of the disclosure may be devised without departing from the basic scope thereof, and the scope thereof is determined by the claims that follow.

What is claimed is:

1. A processing method, comprising:
depositing a film onto a structure of a semiconductor substrate disposed in a processing region of a semiconductor processing chamber, the film comprising a carbon material; and
exposing the semiconductor substrate to a low frequency radio frequency (LFRF) biased plasma treatment to densify the carbon material of the film deposited on the structure.

2. The processing method of claim 1, wherein exposing the semiconductor substrate to the LFRF biased plasma treatment comprises:
forming a plasma from one or more precursors in the processing region; and
biasing plasma effluents of the one or more precursors toward the structure, wherein the plasma effluents convert carbon-hydrogen bonds of the film to carbon-carbon bonds.

3. The processing method of claim 2, wherein biasing the plasma effluents comprises generating and applying a first RF bias power to the semiconductor processing chamber, the first RF bias power having an RF frequency of about 350 kHz or about 2 MHz.

4. The processing method of claim 3, wherein the first RF bias power is pulsed at a pulsing frequency between about 200 Hz and about 2 kHz.

5. The processing method of claim 3, wherein the first RF bias power is applied with a duty cycle of about 10% and about 70%.

6. The processing method of claim 3, wherein the first RF bias power is applied at a power of about 100 W to about 900 W.

7. The processing method of claim 3, wherein the first RF bias power is continuously applied.

8. The processing method of claim 2, wherein biasing the plasma effluents further comprises generating and applying a second bias power to the semiconductor processing chamber, the second bias power having a frequency of about 27 MHz or about 13 MHz.

9. The processing method of claim 8, wherein the second bias power is continuously applied.

10. The processing method of claim 8, wherein the second bias power is applied at a power of about 800 W to about 2900 W.

11. A processing method, comprising:
depositing a carbon gapfill material into a gap of a semiconductor structure disposed in a processing region of a semiconductor processing chamber;
exposing the semiconductor structure to a low frequency radio frequency (LFRF) biased plasma treatment to densify the carbon gapfill material; and
planarizing the carbon gapfill material deposited onto the semiconductor structure.

12. The processing method of claim 11, wherein exposing the semiconductor structure to the LFRF biased plasma treatment comprises:
forming a plasma from one or more precursors in the processing region; and
biasing plasma effluents of the one or more precursors toward the semiconductor structure, wherein the plasma effluents convert carbon-hydrogen bonds of the film to carbon-carbon bonds.

13. The processing method of claim 12, wherein biasing the plasma effluents comprises generating and applying a first RF bias power to the semiconductor processing chamber, the first RF bias power having an RF frequency of about 350 kHz or about 2 MHz.

14. The processing method of claim 13, wherein the first RF bias power is pulsed at a pulsing frequency between about 200 Hz and about 2 kHz.

15. The processing method of claim 13, wherein the first RF bias power is applied with a duty cycle of about 10% and about 70%.

16. The processing method of claim 13, wherein the first RF bias power is applied at a power of about 100 W to about 900 W.

17. The processing method of claim 13, wherein the first RF bias power is continuously applied.

18. The processing method of claim 12, wherein biasing the plasma effluents further comprises generating and applying a second RF bias power to the semiconductor processing chamber, the second RF bias power having a frequency of about 27 MHz or about 13 MHz.

19. The processing method of claim 18, wherein the second RF bias power is continuously applied.

20. A processing method, comprising:
depositing a carbon gapfill material into a gap of a semiconductor structure disposed in a processing region of a semiconductor processing chamber;
exposing the semiconductor structure to a dual-frequency biased plasma treatment to densify the carbon gapfill material, the dual-frequency biased plasma treatment comprising:
applying a first radio frequency (RF) bias comprising a pulsed or continuous low frequency RF (LFRF) bias power; and
applying a second RF bias comprising a continuous high frequency RF (HFRF) bias power; and
planarizing the carbon gapfill material deposited onto the semiconductor structure.
